(19) United States
(12) Patent Application Publication
(10) Pub. No.: US 2016/0379865 A1
(43) Pub. Date: Dec. 29, 2016

(54) METHOD FOR PREPARING SEMICONDUCTOR SUBSTRATE WITH SMOOTH EDGES

(71) Applicant: Shanghai Simgui Tehcnology Co., Ltd., Shanghai (CN)

(72) Inventors: Fei YE, Shanghai (CN); Guoxing CHEN, Shanghai (CN); Meng CHEN, Shanghai (CN)

(21) Appl. No.: 15/162,146

(22) Filed: May 23, 2016

Related U.S. Application Data
(63) Continuation of application No. PCT/CN2014/089981, filed on Oct. 31, 2014.

(30) Foreign Application Priority Data
Nov. 22, 2013 (CN) 201310590117.5

(51) Int. Cl. H01L 21/762; H01L 21/306; H01L 21/02; H01L 21/304

(52) U.S. Cl. CPC H01L 21/76256; H01L 21/304; H01L 21/30625; H01L 21/02021; H01L 21/02013

(57) ABSTRACT

A method is provided for preparing a semiconductor substrate with smooth edges. The method includes: providing a first substrate and a second substrate; forming an insulating layer on a surface of the first substrate and/or the second substrate; bonding the first substrate and the second substrate by using the insulating layer as an intermediate layer; conducting a chamfering process on the bonded first substrate and insulating layer; and conducting edge polishing on the first substrate and insulating layer subjected to the chamfering process.

The present application is a continuation of International Application No. PCT/CN2014/089981, filed on Oct. 31, 2014, which is based upon and claims priority to Chinese Patent Application No. 201310590117.5, filed on Nov. 22, 2013, the entire contents of which are incorporated herein by reference.

### TECHNICAL FIELD

The present disclosure relates to methods for preparing silicon substrates on insulators, and in particular, relates to a method for preparing a semiconductor substrate with smooth edges.

### BACKGROUND

Conventional bonded SOI wafers are prepared by: bonding two oxidized silicon pallets together respectively as a support substrate and a device substrate, reinforcing the bonded substrates at a temperature higher than 1000° C. for 2 hours, then conducting a chamfering process for the bonded substrates by means of grinding and the like, and finally thinning the device substrate to a thickness desired by a SOI device by means of grinding, polishing and the like, to obtain the bonded SOI wafer. During the chamfering process, the oxidation layer, for example, a silica layer, is also ground to define a chamfer angle; in this case, debris of the oxidation layer material generated during the grinding may remain at the edge of the substrate, and the residual debris of the oxidation layer material fails to be removed by a normal cleaning process. FIG. 1 is a transmission electron microscope of a bonded SOI wafer in the related art. The oxidation layer is made from silica. As illustrated by the region marked by the dotted lines in FIG. 1, silica remains in the edge region. The residual silica may result in more particles of the product and wafer debris during the manufacture of the chip, thereby lowering the yield of the products.

### SUMMARY

The technical problem to be solved in the present disclosure is to provide a method for preparing a semiconductor substrate with smooth edges, which is capable of significantly improving the residual debris of the insulating layer material at the edge of the substrate.

To this end, the present disclosure provides a method for preparing a semiconductor substrate with smooth edges, including: providing a first substrate and a second substrate; forming an insulating layer on a surface of the first substrate and/or the second substrate; bonding the first substrate and the second substrate by using the insulating layer as an intermediate layer; conducting a chamfering process on the bonded first substrate and insulating layer; and conducting edge polishing on the first substrate and insulating layer subjected to the chamfering process.

The present disclosure is advantageous in that edge polishing is performed for the first substrate and insulating layer subjected to the chamfering process, which significantly reduces residual debris of the insulating layer material caused by the chamfering step in the edge region of the substrate, and improves the yield of the products.

### BRIEF DESCRIPTION OF THE DRAWINGS

FIG. 1 is a transmission electron microscope of a bonded SOI wafer in the related art;

FIG. 2 is a schematic diagram of steps of a method for preparing a semiconductor substrate with smooth edges according to an embodiment of the present disclosure;

FIG. 3A to FIG. 3G are process flow diagrams of the method for preparing a semiconductor substrate with smooth edges according to an embodiment of the present disclosure;

FIG. 4 is a schematic structural diagram of an edge polishing device according to an embodiment of the present disclosure; and

FIG. 5 is a transmission electron microscope of a bonded SOI wafer prepared by using the method according to the present disclosure.

### DETAILED DESCRIPTION

Embodiments illustrating a method for preparing a semiconductor substrate with smooth edges according to the present disclosure are described in detail with reference to the accompanying drawings.

The terminology used in the present disclosure is for the purpose of describing exemplary embodiments only and is not intended to limit the present disclosure. As used in the present disclosure and the appended claims, the singular forms “a,” “an” and “the” are intended to include the plural forms as well, unless the context clearly indicates otherwise. It shall also be understood that the terms “or” and “and/or” used herein are intended to signify and include any or all possible combinations of one or more of the associated listed items, unless the context clearly indicates otherwise.

It shall be understood that, although the terms “first,” “second,” “third,” etc. may include used herein to describe various information, the information should not be limited by these terms. These terms are only used to distinguish one category of information from another. For example, without departing from the scope of the present disclosure, first information may include termed as second information; and similarly, second information may also be termed as first information. As used herein, the term “if” may include understood to mean “when” or “upon” or “in response to” depending on the context.

Reference throughout this specification to “one embodiment,” “an embodiment,” “exemplary embodiment,” or the like in the singular or plural means that one or more particular features, structures, or characteristics described in connection with an embodiment is included in at least one embodiment of the present disclosure. Thus, the appearances of the phrases “in one embodiment” or “in an embodiment,” “in an exemplary embodiment,” or the like in the singular or plural in various places throughout this specification are not necessarily all referring to the same embodiment. Furthermore, the particular features, structures, or characteristics in one or more embodiments may include combined in any suitable manner.

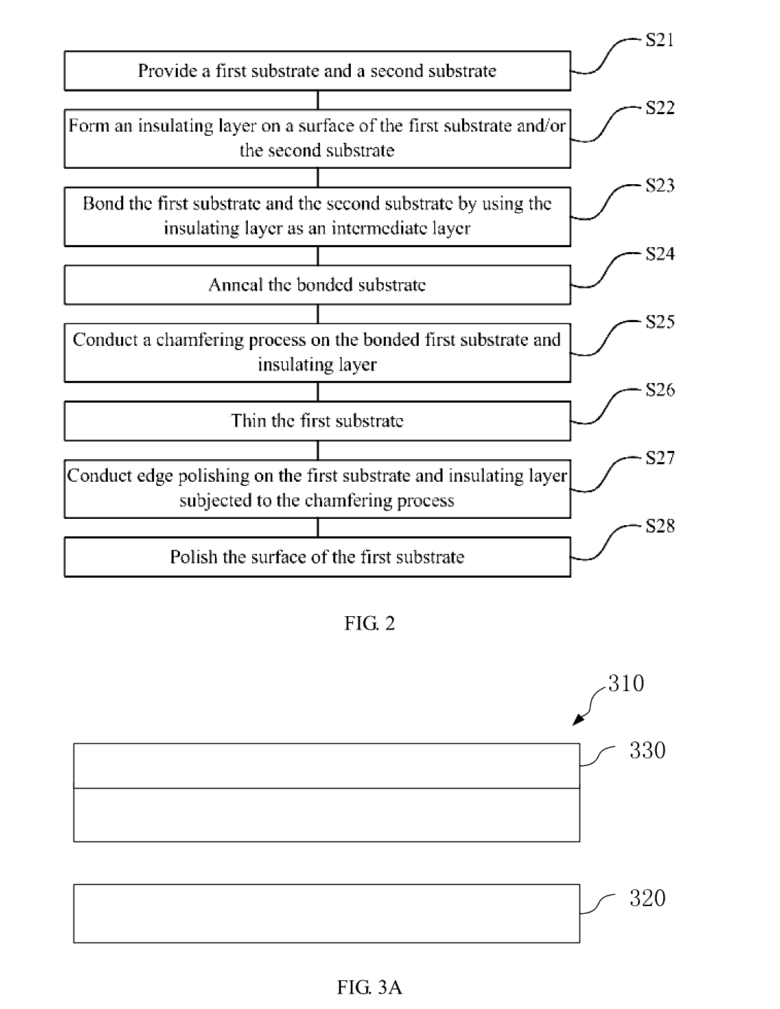

FIG. 2 is a schematic diagram of steps of the method according to an embodiment of the present disclosure. The method includes the following steps: step S21: providing a first substrate and a second substrate; step S22: forming an insulating layer on a surface of the first substrate and/or the second substrate; step S23: bonding the first substrate and the second substrate by using the insulating layer as an intermediate layer; step S24: annealing the bonded substrate; step S25: conducting a chamfering process on the bonded first substrate and insulating layer; step S26: thinning the first substrate; step S27: conducting edge polishing on the first substrate and insulating layer subjected to the chamfering process; and step S28: polishing the surface of the first substrate.

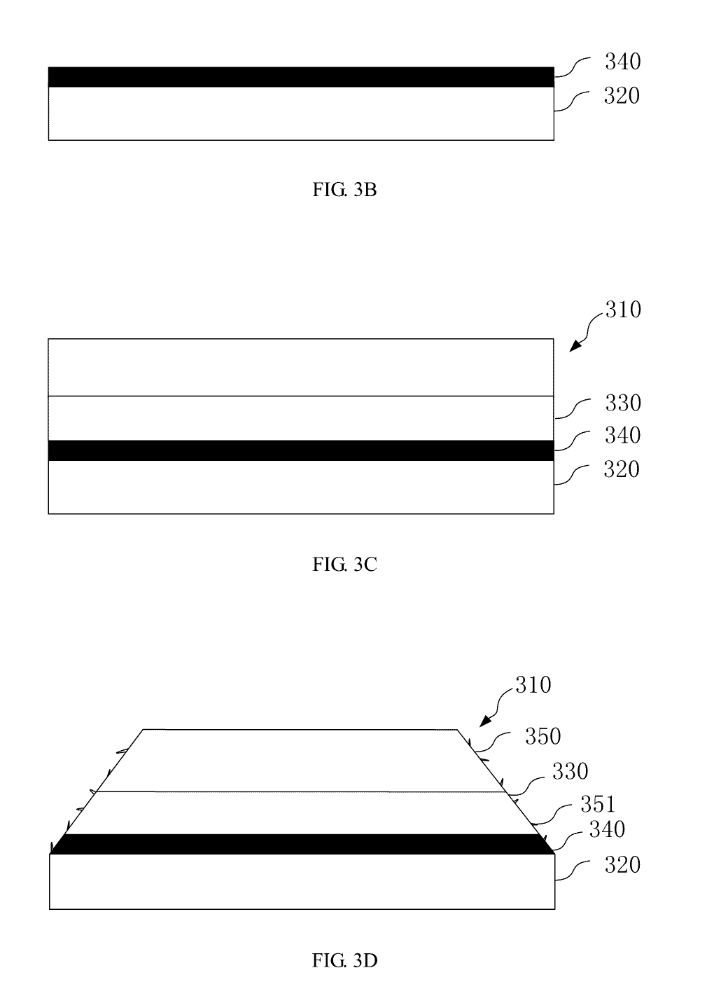

As illustrated in FIG. 3A, with reference to step S21, a first substrate 310 and a second substrate 320 are provided. A device layer 330 having an epitaxy may be further prepared on a surface of the first substrate 310. The first substrate 310 and the second substrate 32—may be lightly-doped or heavily-doped Si substrates, or may be p-type or n-type doped substrate, where the dopant may be B, P, As or other dopant elements. In particular, the second substrate is used as a support substrate of a finally formed semiconductor substrate, which may be prepared by using materials within a more extensive range, even not limited to a semiconductor substrate.

The epitaxy may be a homoepitaxy or an isoepitaxy, and the homoepitaxy is preferably used to achieve a higher crystal quality, for example, the device layer 330 having an epitaxy monocrystalline silicon on the surface of the first substrate made from a monocrystalline silicon. Further, with respect to the device layer 330 made from a monocrystalline silicon material, if a thermally oxidized silica insulating layer needs to be formed on the surface of the device layer 330, the thinning effect caused by the silica process to the device layer 330 needs to be considered. In this case, the thickness of the device layer 330 should be slightly greater than a target thickness of a top semiconductor layer on the surface of the insulating layer.

Further, optionally, before the insulating layer is formed on the surface of the second substrate 320 and/or the first substrate 310, the method further includes a step of correcting the first substrate 310 and the second substrate 320 to reduce a thickness deviation of the first substrate 310 and the second substrate 320. The correction employs one or both of grinding and polishing.

As illustrated in FIG. 3B, with reference to step S22, an insulating layer 340 is formed on the surface of the first substrate 310 and/or the second substrate 320. FIG. 3B illustrates a scenario where the insulating layer 340 is formed on the surface of the second substrate 320. In another embodiment, the insulating layer 340 may also be formed on the surface of the first substrate 310, or the insulating layer 340 may be formed on the surface of both the second substrate 320 and the first substrate 310. The insulating layer 340 may be made from silica, a silicon nitride or a silicon oxynitride, and the formation process may employ chemical vapor deposition or thermal oxidization. In particular with respect to a monocrystalline silicon substrate, a silica insulating layer is formed by preferably using the thermal oxidization.

As illustrated in FIG. 3C, with reference to step S23, the first substrate 310 and the second substrate 320 are bonded by using the insulating layer 340 as an intermediate layer. The bonding herein may be common hydrophilic bonding or hydrophobic bonding, or may be plasma assistant hydrophilic bonding, preferably the hydrophilic bonding and the plasma assistant hydrophilic bonding. When the device layer 330 is formed on the surface of the first substrate 310, the first substrate 310 and the second substrate 320 are bonded by using the insulating layer 340 and the device layer 330 as an intermediate layer.

With reference to step S24, the bonded substrate is annealed. The annealing desires a temperature under which the bonding surface is reinforced such that the requirement on the intensity of the subsequent processes such as grinding and the like is satisfied.

As illustrated in FIG. 3D, with reference to step S25, the bonded first substrate 310 and insulating layer 340 are subjected to a chamfering process to form a chamfer angle 350. For clear illustration of the disclosure of the present disclosure, in the drawings, the chamfer angle 350 is exaggeratedly illustrated. The chamfer angle 350 is formed at the first substrate 310 and the insulating layer 340 by means of mechanical grinding or corrosion. During formation of the chamfer angle 350, the debris formed by grinding or corrosion is partially adhered to the surface experiencing grinding, and debris 351 is schematically illustrated in the drawings. The presence of the debris 351 may result in more particles of the product and wafer debris during the manufacture of the chip.

As illustrated in FIG. 3E, with reference to step S26, the first substrate 310 is thinned. The step of thinning the first substrate 310 may employ a method of firstly grinding and then polishing. The grinding refers to coarsely grinding the first substrate 310 firstly and then finely grinding the first substrate 310. The first substrate is quickly thinned by means of coarse grinding, and damages caused by the grinding to the first substrate 310 are reduced by means of fine grinding. Preferably, the first substrate 310 is directly thinned to the device layer 330, and in this case, the top semiconductor layer is absolutely formed by the device layer 330. If the thickness of the device layer 330 formed on the epitaxy of the surface of the first substrate 310 is greater than a target thickness, this step may further thin the device layer 330 to the target thickness. The advantages lie in that impurities spread from the first substrate 310 to the device layer 330 may be partially removed, and the flatness of the surface of the device layer 330 is improved. In other embodiments of the present disclosure, the thinning step is stopped at a position a specific distance from the device layer 330. In the subsequent steps, the first substrate 310 is thinned to the device layer 330 by means of other thinning process.

As illustrated in FIG. 3F, with reference to step S27, edge polishing is performed for the first substrate 310 and insulating layer 340 subjected to the chamfering process. The edge polishing process completely or partially removes the debris 351 formed by grinding or corrosion. The region for the edge polishing is the region marked by the dotted lines in FIG. 3E. FIG. 3E merely schematically illustrates the polishing region on one side. In practice, the polishing region should surround the bonded substrate. An edge polishing device is applied for the edge polishing.

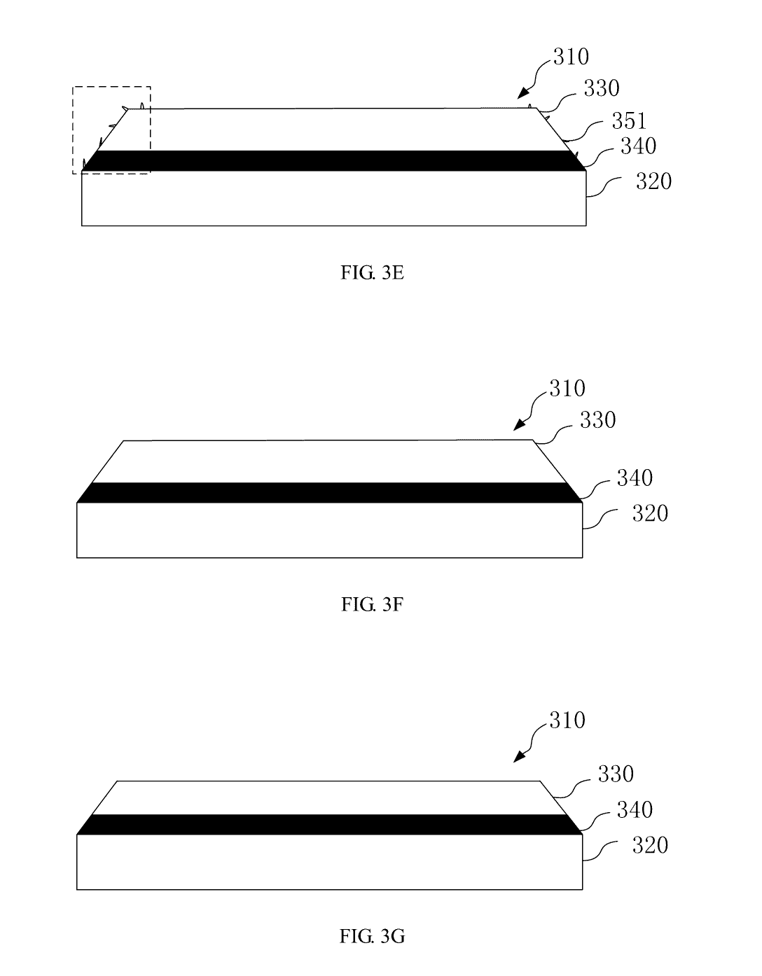

FIG. 4 is a schematic structural diagram of an edge polishing device according to an embodiment of the present disclosure. Referring to FIG. 4, the edge polishing device includes a stage 410, a polishing head 420 and a polishing pad 430. The stage 410 bears and fixes a sample 440 to be polished, and the polishing pad 430 is coupled to the polishing pad 420 and operable to polish the sample 440 to be polished. When the sample 440 to be polished is being polished, the stage 410 bears the sample 440 to be polished and rotates at a low speed, the polishing head 420 rotates at a high speed and then slowly reduces its rotation speed until the polishing pad 430 is in contact with the sample 440 to be polished. In this specific embodiment, the stage 410 fixes, by means of vacuum adsorbing, the sample 440 to be polished. In other specific embodiments, the sample to be polished may be fixed by means of mechanical fixing and the like, to prevent the sample 440 to be polished from moving during the edge polishing.

As illustrated in FIG. 3G with reference to step S28, the surface of the first substrate 310 is polished, such that the surface of the first substrate 310 is flat and smooth. The polishing may be double-face polishing or single-face polishing, or may be double-face plus single-face polishing, which is preferably used herein.

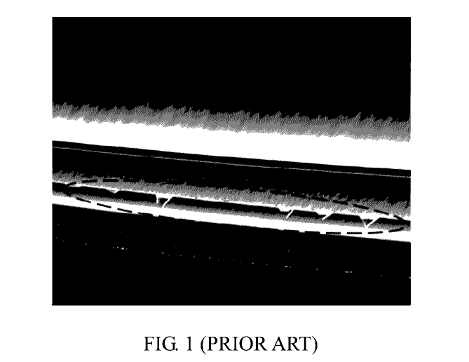

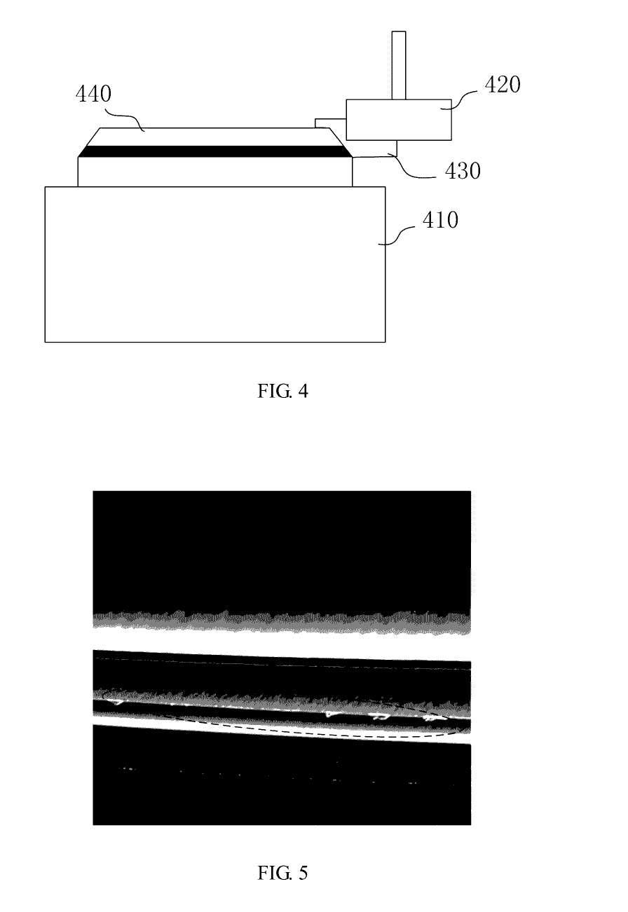

FIG. 5 is a transmission electron microscope of a bonded SOI wafer prepared by using the method according to the present disclosure. A comparison between the region marked by the dotted lines in FIG. 5 and the region marked by the dotted lines in FIG. 1 shows that the semiconductor substrate prepared by using the method according to the present disclosure has smooth edges, the residual debris of the insulating layer material at the edge of the substrate is reduced, and the yield of the products is significantly improved.

In the disclosure, prior to forming an insulating layer on a surface of the first substrate and/or the second substrate, the method may further include a step of correcting the first substrate and the second substrate to reduce a thickness deviation of the first substrate and the second substrate.

Here, upon the bonding step, the method may further include a step of annealing the bonded substrate. Further, the chamfering process employs one or both of mechanical grinding and corrosion. Further, upon the chamfering step, the method may further include a step of thinning the first substrate, where the thinning step employs one or more of mechanical grinding, corrosion and chemical mechanical grinding. Further, upon the bonding step, the method may further include a step of polishing the surface of the first substrate. Further, a device layer is further prepared on the surface of the first substrate.

Described above are preferred examples of the present disclosure. It should be noted that persons of ordinary skill in the art may derive other improvements or polishments without departing from the principles of the present disclosure. Such improvements and polishments shall be deemed as falling within the protection scope of the present disclosure.

What is claimed is:

1. A method for preparing a semiconductor substrate with smooth edges, comprising:
providing a first substrate and a second substrate;
forming an insulating layer on a surface of the first substrate and/or the second substrate;
bonding the first substrate and the second substrate by using the insulating layer as an intermediate layer;
conducting a chamfering process on the bonded first substrate and insulating layer; and
conducting edge polishing on the first substrate and insulating layer subjected to the chamfering process.

2. The method for preparing a semiconductor substrate with smooth edges according to claim 1, wherein prior to forming an insulating layer on a surface of the first substrate and/or the second substrate, the method further comprises a step of correcting the first substrate and the second substrate to reduce a thickness deviation of the first substrate and the second substrate.

3. The method for preparing a semiconductor substrate with smooth edges according to claim 1, further comprising annealing the bonded substrate after bonding the first substrate and the second substrate.

4. The method for preparing a semiconductor substrate with smooth edges according to claim 1, wherein the chamfering process employs one or both of mechanical grinding and corrosion.

5. The method for preparing a semiconductor substrate with smooth edges according to claim 1, wherein upon the chamfering step, the method further comprises a step of thinning the first substrate, wherein the thinning step employs one or more of mechanical grinding, corrosion and chemical mechanical grinding.

6. The method for preparing a semiconductor substrate with smooth edges according to claim 1, further comprising polishing the surface of the first substrate after bonding the first substrate and the second substrate.

7. The method for preparing a semiconductor substrate with smooth edges according to claim 1, further comprising:
disposing a device layer on the surface of the first substrate.
